(19) United States
(12) Patent Application Publication
(10) Pub. No.: US 2024/0314975 A1
(43) Pub. Date: Sep. 19, 2024

(54) Electronic Package Construction for Immersion Cooling of Integrated Circuits

(71) Applicant: MTS IP Holdings Ltd, George Town (KY)

(72) Inventors: Brian H. Kim, Fremont, CA (US); Jianhua Bi, San Jose, CA (US); Ioannis Manousakis, Zürich (CH)

(73) Assignee: MTS IP Holdings Ltd, George Town (KY)

(21) Appl. No.: 18/460,070

(22) Filed: Sep. 1, 2023

Related U.S. Application Data
(63) Continuation of application No. PCT/US2023/067058, filed on May 16, 2023.
(60) Provisional application No. 63/489,895, filed on Mar. 13, 2023.

(51) Int. Cl. H05K 7/20; H01L 23/367; H01L 23/40

(52) U.S. Cl. CPC H05K 7/203; H01L 23/3675; H01L 23/40; H05K 7/20318

(57) ABSTRACT

Assemblies and related methods to cool high-power integrated circuits are described. A heat-dissipative element is thermally coupled directly to a semiconductor die with a thermal interface material and contacts a coolant liquid.

### CROSS-REFERENCE TO RELATED APPLICATIONS

The present application is a bypass continuation of international patent application No. PCT/US2023/067058, titled “Electronic Package Construction for Immersion Cooling of Integrated Circuits,” and filed May 16, 2023, which is incorporated herein by reference in its entirety. International patent application No.: PCT/US2023/067058 claims a priority benefit, under 35 U.S.C. § 119(e), to U.S. provisional application Ser. No. 63/489,895 filed on Mar. 13, 2023, titled “Electronic Package Construction for Immersion Cooling of Integrated Circuits,” which is incorporated herein by reference in its entirety.

### BACKGROUND

As feature sizes and transistor sizes have decreased for integrated circuits (ICs), the amount of heat generated by a single chip, such as a microprocessor, has increased. Chips that once were air cooled have evolved to chips needing more heat dissipation than can be provided by air alone. In some cases, immersion cooling of chips in a coolant liquid is employed to maintain IC chips at appropriate operating temperatures.

### SUMMARY

The present disclosure relates to heat-dissipating structures, cooling assemblies, and methods for cooling densely-packed, high-power IC chips. A thermally-conductive, heat-dissipative element can be thermally coupled directly to each IC die to improve heat dissipation from the die into a coolant liquid. The heat-dissipative element can be packaged with the die and populated onto a board with other dies packaged in the same way to form the densely-packed, high-power IC chips (e.g., densely-packed microprocessors and/or graphical processors for an advanced computing system). The dies and heat-dissipative elements can be cooled via immersion cooling. By adhering the heat-dissipative element directly to the die, the area and volume occupied by the combination of die and heat-dissipative element can be significantly reduced by factors of 4 and 8, respectively, or more compared to conventional cooling assemblies.

Some implementations relate to cooling assemblies including a semiconductor die. A cooling assembly can include the semiconductor die having a first surface and a heat-dissipative element having a second surface on a first side of the heat-dissipative element and a third surface on a second side of the heat-dissipative element opposite the second surface. The third surface can be arranged to physically contact a coolant liquid. The cooling assembly can further include a thermal interface material in physical contact with the first surface of the semiconductor die and in physical contact with the second surface of the heat-dissipative element.

Some implementations relate to methods of cooling a semiconductor die. An example method can include acts of: receiving heat directly from a first surface of the semiconductor die in a thermal interface material that is in physical contact with the first surface of the semiconductor die; transferring heat from the thermal interface material directly into a second surface of a heat-dissipative element that is in physical contact with the thermal interface material; and transferring heat from a third surface of the heat-dissipative element directly into a coolant liquid that is in physical contact with the third surface.

Some implementations relate to methods of making a cooling assembly to cool a semiconductor die. An example method can include acts of: applying a thermal interface material to a first surface of the semiconductor die; and physically contacting a second surface of a heat-dissipative element to the thermal interface material, wherein the heat-dissipative element includes a boiling enhancement coating on a third surface to physically contact a coolant liquid.

Some implementations relate to cooling assemblies that include semiconductor die. An example cooling assembly can include the semiconductor die having a first surface and a heat-dissipative element having a second surface on a first side of the heat-dissipative element and a third surface on a second side of the heat-dissipative element opposite the second surface. The third surface can be arranged to thermally couple to a coolant liquid. The cooling assembly can further include a thermal interface material disposed between the first surface of the semiconductor die and the second surface of the heat-dissipative element to transfer heat from the semiconductor die to the heat-dissipative element, wherein there is no protective lid disposed between the semiconductor die and the heat-dissipative element.

All combinations of the foregoing concepts and additional concepts discussed in greater detail below (provided such concepts are not mutually inconsistent) are part of the inventive subject matter disclosed herein. In particular, all combinations of subject matter appearing in this disclosure are part of the inventive subject matter disclosed herein. The terminology used herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally and/or structurally similar elements).

FIG. 1 depicts a cooling assembly to dissipate heat from a semiconductor die via immersion cooling.

FIG. 2 depicts an example of a two-phase immersion cooling system that can be used with the heat-dissipative elements described herein.

FIG. 3A depicts an example of an assembly for dissipating heat from a semiconductor die.

FIG. 3B depicts an additional example of an assembly for dissipating heat from a semiconductor die.

FIG. 4A depicts an additional example of an assembly for dissipating heat from a semiconductor die.

FIG. 4B depicts an additional example of an assembly for dissipating heat from a semiconductor die.

FIG. 5 depicts an example of a method for dissipating heat from a semiconductor die that can be implemented with the assemblies of FIG. 3A through FIG. 4B.

FIG. 6 depicts results from a numerical simulation of heat dissipation in a cooling assembly like that of FIG. 3B.

### DETAILED DESCRIPTION

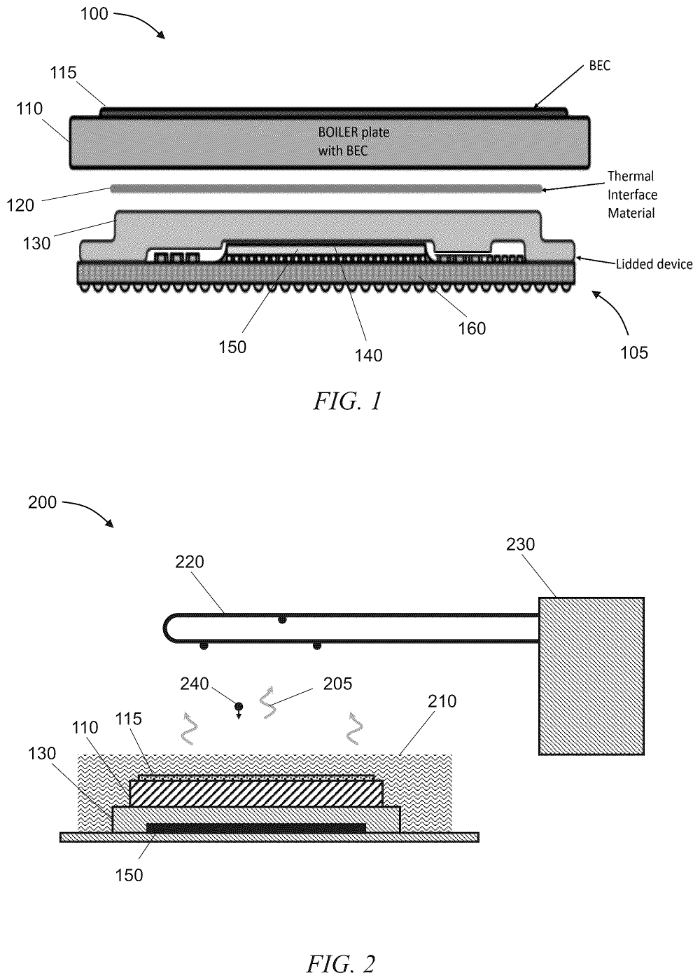

FIG. 1 depicts, in partial exploded view, a cooling assembly 100 for dissipating heat from a semiconductor die 150 via immersion cooling. The cooling assembly 100 includes a heat-dissipative element 110 (referred to as a “boiler plate” in some applications) that is thermally coupled to a protective lid 130 with a first thermal interface material (TIM) 120. The protective lid 130 is also thermally coupled to the semiconductor die 150 with a second TIM 140. The protective lid 130 and semiconductor die 150 can both be mounted on and attach to a printed circuit board (PCB) 160 in device package 105 that is commercially available. Typically, the heat-dissipative element 110 is attached to the device package 105 with mechanical fasteners (e.g., screws and springs, not shown in FIG. 1) that force the heat-dissipative element 110 against the first TIM 120 and protective lid 130. The protective lid 130 and mechanical fasteners can cause the cooling assembly 100 to occupy an area and volume significantly larger than the semiconductor die 150 (e.g., up to ten times the area or more and up to one hundred times the volume or more).

The cooling assembly 100 of FIG. 1 can be used for two-phase immersion cooling of a semiconductor die 150, such as a microprocessor (e.g., a central processing unit (CPU) and/or graphic processing unit (GPU)), a digital signal processing (DSP) die, an application-specific integrated circuit (ASIC), field-programmable gate array (FPGA), and/or other densely patterned semiconductor die. In a two-phase immersion-cooling system 200 (depicted in FIG. 2), heat flows from the semiconductor die 150 where it is generated, through the second TIM 140 into the protective lid 130, through the first TIM 120, and into the heat-dissipative element 110. The heat-dissipative element 110 is in thermal contact with a coolant liquid 210 that can flow over and extract heat from the heat-dissipative element 110. The amount of heat delivered by the heat-dissipative element 110 to the coolant liquid 210 is enough to boil the coolant liquid. The vapor 205 from the boiled coolant liquid 210 can be cooled and condensed back to liquid droplets 240, for example, by a condenser coil 220. A heat transfer fluid, such as chilled water, from a chiller 230 can be circulated through the condenser coil 220 to condense the vapor 205 on exterior surfaces of the condenser coil 220. Liquid droplets 240 from the condensed vapor can drip and/or flow back to the coolant liquid 210 that contacts the heat-dissipative element 110.

The heat-dissipative element 110 and the protective lid 130 can have comparatively high thermal conductivities. For example, one or both of these elements can be formed from a metal, such as copper (thermal conductivity approximately 400 W m⁻¹ K⁻¹) or aluminum (thermal conductivity as much as approximately 250 W ml K⁻¹). In comparison, the first TIM 120 and the second TIM 140 can have low values of thermal conductivity. For example, the thermal interface materials 120, 140 may be thermally-conductive adhesives (thermal conductivity on the order of 2 W m⁻¹ K⁻¹).

To improve thermal performance in two-phase immersion cooling system 200, the heat-dissipative element 110 can include a boiling enhancement coating (BEC) 115 on at least one surface. The BEC 115 can be formed from copper or a copper alloy and can be porous, for example, though BECs can take various forms. In some cases, the BEC is a micro porous copper coating having a thickness from approximately or exactly 50 microns to 500 microns thick (which may be produced by electroplating and/or etching). In some implementations, the BEC 115 comprises a mesh copper layer bonded (e.g., via resistance heating) to at least a top surface of the heat-dissipative element 110. In some cases, the BEC 115 is applied as particulates to at least one smooth surface of the heat-dissipative element 110 and then subsequently sintered to adhere to one another and to the heat-dissipative element 110. The BEC 115 provides a large surface area to contact the coolant liquid 210 and can increase the heat transfer coefficient from the heat-dissipative element 110 to the coolant liquid 210 by up to a factor of 15 versus a smooth surface on the heat-dissipative element 110. Accordingly, BECs 115 can increase thermal conductivity to, and accelerate the boiling of, the coolant liquid 210.

A heat-dissipative element 110 with a BEC 115 can increase heat transfer away from the semiconductor die 150 compared to a heat-dissipative element 110 without a BEC. By removing heat more quickly from the semiconductor die 150, the performance of high-power devices (such as microprocessors used for CPUs, GPUs, accelerators for artificial intelligence computing, and other integrated circuits operating at power levels over 300 watts) can be improved. The microprocessors can be mounted on cards used in datacenters or high-performance computing (HPC) applications, for example. In some cases, the electrical power drawn by the semiconductor die 150 can be from 300 watts to 600 watts or even higher.

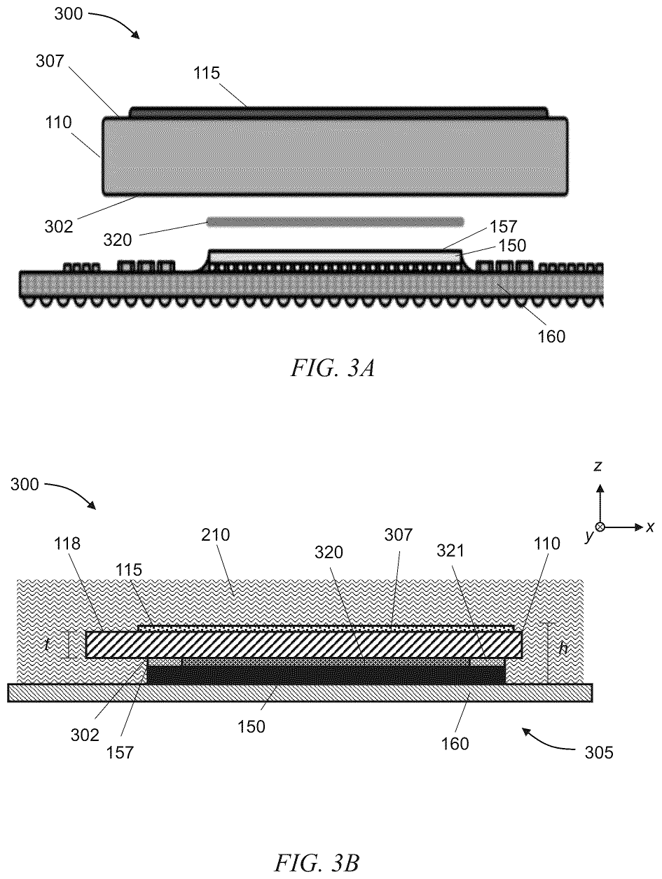

The inventors have recognized and appreciated that removal of the protective lid 130 covering the semiconductor die 150 and thermally coupling the heat-dissipative element 110 directly to the semiconductor die 150 can increase heat removal from the semiconductor die 150, allow packaging of the heat-dissipative element 110 with the semiconductor die 150, and significantly reduce the area and volume occupied by the cooling assembly. FIG. 3A depicts, in partial exploded view, an example of a cooling assembly 300 with improved heat dissipation and size reduction. The cooling assembly 300 of FIG. 3A can be used for two-phase and single-phase immersion cooling of a semiconductor die 150, such as a microprocessor (e.g., a central processing unit (CPU) or graphic processing unit (GPU)), a digital signal processing (DSP) die, an application-specific integrated circuit (ASIC), field-programmable gate array (FPGA), or other densely patterned, very-large-scale-integration semiconductor die.

FIG. 3B depicts another implementation of a cooling assembly 300 that includes the semiconductor die 150. The cooling assembly 300 can be provided as a semiconductor device package 305 that includes the semiconductor die 150, the heat dissipative element 110, at least one TIM 320 between the semiconductor die 150 and the heat-dissipative element 110, and the printed circuit board 160. When placed in operation, the device package 305 can be immersed in a coolant liquid 210. The cooling assembly 300 comprises a heat-dissipative element 110 that directly thermally couples to the semiconductor die 150 through at least one TIM 320. The heat-dissipative element 110 can include a BEC 115 extending over most of at least one surface of the heat-dissipative element. The BEC can be located on a surface of the heat-dissipative element 110 that is opposite the surface that contacts the TIM 320. Unlike in cooling assembly 100, there is no protective lid 130 and no second TIM 140 in the cooling assembly 300 through which heat must flow to reach coolant liquid 210 that contacts the heat-dissipative element 110.

The heat-dissipative element 110 can include a smooth surface 118. The smooth surface can be used to apply a marking to the heat-dissipative element 110 (e.g., to identify the semiconductor die under the heat-dissipative element 110). Additionally or alternatively, the smooth surface 118 can be used to pick up at least the heat-dissipative element 110 or the package (semiconductor die 150, heat-dissipative element 110, and PCB 160) using a vacuum chuck, for example. A normal direction from the smooth surface (an arrow perpendicular to the plane of the smooth surface 118) can point generally away from the semiconductor die 150 such that the smooth surface 118 is accessible (to a vacuum chuck, for example) and visible.

By removing the thermal resistance of the protective lid 130 and the second TIM 140, which has low thermal conductivity, heat can transfer more quickly from the semiconductor die 150, through the TIM 320, and through the heat-dissipative element 110 to the coolant liquid 210 and thereby further improve operation of high-power devices employing the cooling assembly 300 of FIG. 3B. The inventors have also found that selecting a thickness/of the heat-dissipative element 110 above the semiconductor die 150 can improve thermal dissipation and lower the temperature of the semiconductor die 150. For example, a lowest temperature of the semiconductor die 150 can be obtained for a thickness/in a range from approximately or exactly 0.5 millimeter (mm) to approximately or exactly 4 mm). Thicker and thinner heat-dissipative elements result in higher temperatures.

Additionally, the size of the cooling assembly 300 can be reduced significantly compared to the cooling assembly 100 of FIG. 1, because the protective lid 130 and mechanical fasteners are removed. As an example, the reduction in height h (extending in the z direction) can be by at least 50% or even more. In one case, the height of a cooling assembly 100 like that shown in FIG. 1 is approximately 10 mm, whereas the height of the cooling assembly 300 of FIG. 3B can be less than 3 mm. The area (real estate) of the cooling assembly 300 (extending in directions x and y approximately parallel (i.e., within 20 degrees of parallel including being parallel) to the upper surface of the semiconductor die 150 that contacts the TIM 320) can also be significantly reduced. For example, the spatial extent of the cooling assembly 300 in the x and y directions can each be reduced by 50% or more compared to that for the cooling assembly 100 depicted in FIG. 1. As a result, the area of the cooling assembly 300 can be reduced by a factor of up to four or more and the volume occupied by the cooling assembly 300 can be reduced by a factor of up to eight or more compared to a conventional cooling assembly.

Reduction in the area (x and y directions) occupied by the cooling assembly 300 allows more device packages 305 (and semiconductor dies 150) to be populated side by side on a printed circuit board that may mount in a rack with other similar printed circuit boards for an advanced computing system. Reduction in the height h of the cooling assembly 300 can allow smaller spacing between the rack-mounted PCBs, so that higher densities of semiconductor dies can be assembled in an advanced computing system. As an example, the device package size can be reduced to as small as 10 mm×10 mm×3 mm. Device packages 305 can be arrayed on each printed circuit board with a spacing of 2 mm between each package 305 in x and y directions. The PCB boards can be spaced 8 mm apart, such that each package 305 is located in a volume measuring 12 mm×12 mm×8 mm. For a semiconductor die having a size of 5 mm×5 mm×5 mm, the volume occupancy would be about 11%. High packing densities and volume occupancy may be possible by increasing the surface area of the heat-dissipating elements 110 that contacts the coolant liquid 210 (e.g., by corrugating the contact surface(s)).

In some implementations, adhesion of the heat-dissipative element 110 to the semiconductor die 150 can be improved by using two types of thermally-conductive adhesives. For example, a first TIM 320 can comprise a first type of thermally-conductive adhesive, gel, or paste that has a higher thermal conductivity than a second TIM 321 that is used to improve adhesion of the heat-dissipative element 110 to the semiconductor die 150. The second TIM 321 can have superior adhesion performance to the first TIM 320 and prevent delamination of the heat-dissipative element 110 from the semiconductor die 150. The first TIM 320 can cover more than 50% of the upper, contact surface of the semiconductor die 150. The second TIM 321 can be located peripherally around the first TIM 320. The two TIMs can conduct heat in parallel from the semiconductor die 150 to the heat-dissipative element 110, by which the first TIM provides higher heat flow from a hotter central region of the semiconductor die.

The heat-dissipative element 110 can have a first surface 302 that thermally couples to an exposed surface 157 of the semiconductor die 150 through the TIM 320 (and through TIM 321 if used). The TIM(s) 320, 321 can comprise one or more layers of thermally-conductive material(s). In some implementations, only one TIM 320, 321 is located between the first surface 302 of the heat-dissipative element 110 and the exposed surface 157 of the semiconductor die 150 at any location on the surface of the semiconductor die 150, such that the TIM 320, 321 physically contacts the exposed surface 157 of the semiconductor die 150 on one side of the TIM 320, 321 and physically contacts the first surface 302 of the heat-dissipative element 110 on an opposite side of the TIM 320, 321. Heat can be disspated into the coolant liquid primarily through a second surface 307 of the heat-dissipative element 110.

The exposed surface 157 of the semiconductor die 150, the first surface 302, and the second surface 307 can extend mostly in planar directions (e.g., directions that are within 20 degrees of an x-y plane for the illustrated embodiment). These three surfaces can define three planes that are approximately parallel to each other. For example, each surface (even though topologically modulated or roughened) may extend along a plane, and each of the planes can be within 20 degrees of being exactly parallel to each other, including being parallel. In some implementations, substantially the entire second surface 307 of the heat-dissipative element 110 is arranged to contact coolant liquid 210. At least 70%, at least 80%, or even at least 90% of the second surface 307 of the heat-dissipative element 110 can be arranged to contact coolant liquid 210. In other implementations, the entire second surface 307 of the heat-dissipative element 110 is arranged to contact coolant liquid 210.

The heat-dissipative element 110 can be formed from at least one material having high thermal conductivity (e.g., a thermal conductivity of at least 20 W m⁻¹ K⁻¹). Example materials include copper, copper alloys (such as beryllium copper), aluminum, aluminum alloys, silver, chromium, molybdenum, and niobium. Other materials may also be used for the heat-dissipative element 110 such as, but not limited to, semiconductors (e.g., silicon, silicon carbide, and gallium nitride) and ceramics (e.g., aluminum nitride, boron nitride, and beryllia).

Preferably, the first surface 302 of the heat-dissipative element 110 has a surface area that is at least the same size and/or shape as the exposed surface 157 of the semiconductor die 150, though the surface area of the first surface 302 may have a different shape and/or smaller size than the exposed surface 157 in some applications (e.g., applications where less heat dissipation can be tolerated and size and/or fit constraints are imposed on the heat-dissipative element 110 for packaging). In some cases, the first surface 302 has a surface area that is larger than the exposed surface 157 of the semiconductor die 150 so that heat from the semiconductor die can be spread over a larger area on the heat-dissipative element 110 and transfer to the liquid coolant 210 through a larger surface area from the heat-dissipative element. In such cases, the first surface 302 can have an area that is not more than 10% larger than the area of the exposed surface 157 of the semiconductor die 150, though other size limits may be used (e.g., not more than 20% larger, not more than 40% larger, not more than 80% larger, not more than 100% larger, not more than 200% larger, and even not more than 400% larger). In some cases, larger sizes may be used. At least a portion of the first surface 302 can conform to the topography (e.g., flat) of the exposed surface 157 on the semiconductor die 150.

A second surface 307 of the heat-dissipative element 110 can have any shape and size. The second surface 307 can directly and physically contact the coolant liquid 210. The second surface 307 can include a BEC 115, as described above, that can physically contact the coolant liquid 210. The BEC 115 can extend over part or all of the second surface and may further extend over additional surfaces of the heat-dissipative element 110. The second surface can have any topography (e.g., flat, corrugated, or otherwise structured).

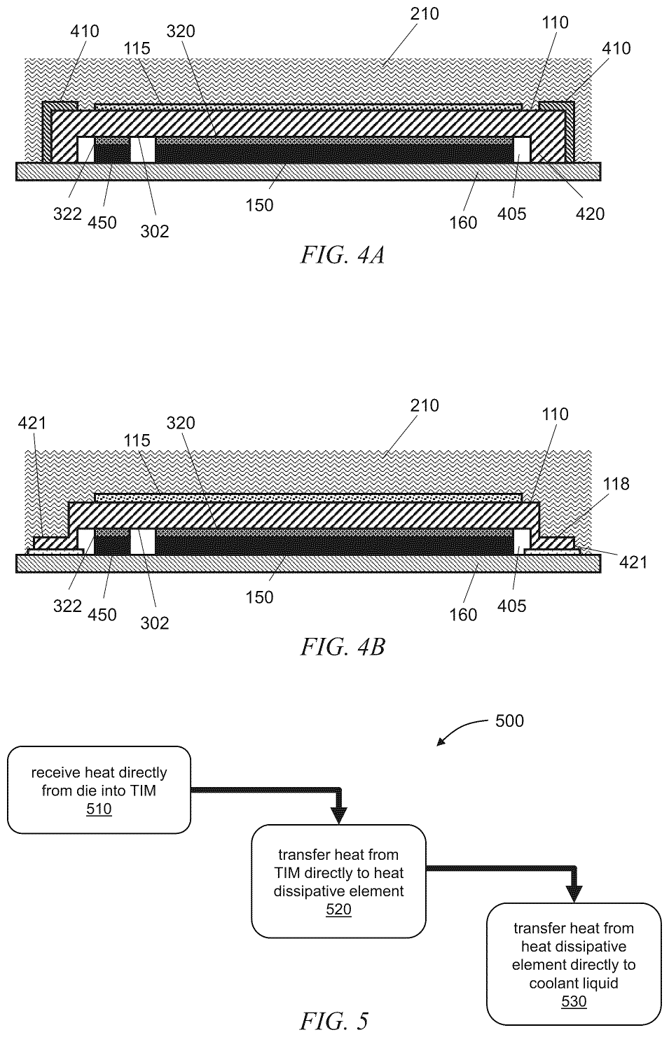

The heat-dissipative element 110 may couple to the semiconductor die 150 in any one of several ways. In some cases, the TIM 320 comprises a thermally-conductive adhesive or a solder that retains the heat-dissipative element 110 to the semiconductor die 150 and allows heat to flow therethrough. An example adhesive that can be included in the TIM 320 or that may entirely form the TIM 320 is the TM 150EB Solderable Conductive Adhesive available from YINCAE Advanced Materials company of Albany, New York. When cured, the adhesive has a Young's modulus of 100 MPa and a thermal conductiving of over 86 W m⁻¹ K⁻¹. An example solder is an indium alloy solder. In some implementations, the TIM 320 retains the heat-dissipative element 110 to the semiconductor die 150 without any mechanical fasteners (e.g., screws, clips, springs, retaining pins, clamps, or combination thereof), by providing adhesion between the heat-dissipative element 110 and semiconductor die 150, for example. In other implementations, the heat-dissipative element 110 is mechanically coupled to the semiconductor die 150 by mechanical fasteners 410, as depicted in FIG. 4A. The mechanical fasteners 410 can include screws, clips, springs, retaining pins, clamps, or some combination thereof and be arranged to retain the heat-dissipative element 110 and thermal interface material 320 at least against the semiconductor die 150. A resilient fastener 410 can retain the heat-dissipative element 110 in place while allowing for different thermal expansion between the heat-dissipative element 110 and the semiconductor die 150. A resilient force from the fastener 410 can aid in thermally coupling the heat-dissipative element 110 and the semiconductor die 150 by creating a force that acts to compress the TIM 320 between the heat-dissipative element 110 and the semiconductor die 150, increasing thermal contact therebetween.

In some implementations, the TIM 320 can comprise a polymer (such as silicone, a urethane, or epoxy) in which highly conductive particles (e.g., aluminum, silver, beryllium, silicon, boron nitride, or copper particles) are suspended. The TIM 320 can be in the form of a thermally-conductive adhesive or thermally-conductive gel that retains sufficient flexibility to allow for differences in thermal expansion of the heat-dissipative element 110 and the semiconductor die 150, which can have different coefficients of thermal expansion (different CTEs). Another thermally-conductive adhesive that could be included in a TIM 321 is the ESM-H6615 adhesive available from CSI Chemical Company of Haimen, Jiangsu Provence, China. The adhesive, when cured, has a thermal conductivity of about 15 W m⁻¹ K⁻¹ and a Young's modulus of about 24 MPa. An example gel is the X-23-8057 silicone gel available from Shin-Etsu Silicones, Inc. of Akron, Ohio. The gel has a thermal conductivity of 7 W m⁻¹ K⁻¹. In some implementations, the TIM 320 can comprise a malleable material, such as a silver foil and/or an indium foil. The TIM 320 preferably can reduce mechanical stress between the semiconductor die 150 and the heat-dissipative element 110 arising from a difference in a first coefficient of thermal expansion for the semiconductor die 150 and a second coefficient of thermal expansion for the heat-dissipative element 110 when the semiconductor die operates at elevated temperatures. The hardness of the TIM 320 material(s) can be less than a Shore D hardness of 60 and can be as low as a Shore 00 10 hardness. In some cases, the hardness of the TIM 320 can be between Shore 00 10 and Shore 00 80, between Shore 00 80 and Shore 00 100, or between Shore D 20 and Shore D 60, though subranges within these ranges are also possible. The Young's modulus of TIM material(s) can be as low as 50 Pa and as high as 500 MPa. The thickness of the TIM 320 can be in a range from 10 microns to 1 mm or within any subrange within this range of values (e.g., from 10 microns to 200 microns, from 50 microns to 500 microns, etc.)

The hardness of the TIM 320 and its thickness can be selected to accommodate thermally-induced stress in the TIM 320 arising from different CTEs of the heat-dissipative element 110 and the semiconductor die 150. To accommodate the thermally-induced stress, the TIM 320 may not go into plastic deformation. The stress generated may be when the heat-dissipative element 110 and the semiconductor die 150 change in temperature from a low specified operating temperature (e.g., −40° C.) to a maximum operating temperature (e.g., 120° C.).

FIG. 4A depicts an implementation where the heat-dissipative element 110 includes feet 420 that can contact the PCB 160 or that can contact a component on the PCB 160. The feet can provide stability to the heat-dissipative element, particularly when adhered to the PCB 160. The heat-dissipative element 110 of FIG. 4A and FIG. 4B can protect the semiconductor die 150 (e.g., retaining the protective function of the protective lid 130 of FIG. 1) while additionally providing heat dissipation. In some cases, the heat-dissipative element 110 and PCB 160 can form a sealed chamber 405, surrounding the semiconductor die 150, that prevents the coolant liquid 210 from contacting the semiconductor die 150. In some implementations, the chamber 405 may be open allowing coolant liquid 210 to flow through the chamber. According to some implementations, the first surface 302 of the heat-dissipative element 110 can thermally couple to at least one second device 450 that is integrated on the PCB 160. For example, the semiconductor die 150 and a second device 450 can thermally couple in parallel to the first surface 302 of the heat-dissipative element 110. In some cases, there can be a second TIM 322 between the second device 450 and the first surface 302 of the heat-dissipative element 110. The second TIM 322 can be a single layer of material or multiple layers of materials, like the TIM 320. The second TIM 322 can physically contact the second device 450 on one side and physically contact the first surface 302 of the heat-dissipative element 110 on an opposite side. The second device 450 may be a power transistor, ASIC, or DSP die, for example. In some cases, the semiconductor die 150 can be a CPU and the second device 450 can be a GPU. According to some implementations, the heat-dissipative element 110 can be implemented as a heat spreader that thermally couples to the semiconductor die 150 and second device 450, as described in U.S. provisional patent application No. 63/500,167 titled “Direct to Chip Heat Spreader and Boiler Enhancement Coatings for Microelectronics,” filed May 3, 2023, which application is incorporated herein by reference in its entirety.

FIG. 4B depicts another implementation where the heat-dissipative element 110 includes extended feet 421 that can contact the PCB 160. The extended feet 421 may extend around part or the entire periphery of the heat-dissipative element 110. The extended feet 421 can include a smooth surface 118. The smooth surface can be used to apply a marking to the heat-dissipative element 110 (e.g., to identify the semiconductor die under the heat-dissipative element 110). Additionally or alternatively, the smooth surface 118 can be used to pick up at least the heat-dissipative element 110 or the package (semiconductor die 150, heat-dissipative element 110, and PCB 160) using a vacuum chuck, for example. Further the extended feet 421 (and feet 420) can be used to adhere the heat-dissipative element 110 to the PCB 160 or other component on the PCB. An adhesive (e.g., thermal cure adhesive, epoxy, thermally-conductive adhesive, etc.) can be used to adhere the heat-dissipative element 110 to the PCB 160 and improve robustness of the assembly.

The structures of FIG. 3A through FIG. 4B can be used with two-phase immersion cooling systems 200 as described above in connection with FIG. 2. The structures can also be used with single-phase immersion cooling systems where the coolant liquid 210 does not boil and is instead cycled through a chiller or other heat sink to remove heat from the coolant liquid 210. The coolant liquid 210 can be any suitable liquid used for single-phase immersion cooling or two-phase immersion cooling, though choice of the coolant liquid 210 can depend upon the material(s) selected to make the heat dissipation element 110. A suitable coolant liquid 210 is one that at least does not noticeably dissolve or corrode the heat-dissipative element 110 and the BEC 115. One example coolant liquid for two-phase immersion cooling is SmartCoolant synthetic fluid available from Submer Labs of Barcelona, Catalonia, Spain. Coolant liquids from the family of Fluorinert™ Electronic Liquids (available from 3M™ of Maplewood, Minnesota, U.S.) may also be used. For two-phase immersion cooling, coolant liquids 210 having different boiling points are commercially available. A coolant liquid 210 selected for an application can one that has a boiling point below a maximum temperature reached by the heat-dissipative element when the semiconductor die is in use.

FIG. 5 illustrates steps associated with a method 500 of removing heat from a semiconductor die according to some implementations described herein. The method 500 can include acts of receiving (510) heat directly from the semiconductor die 150 in a thermal interface material 320, 321 that is in physical contact with the semiconductor die 150. By directly receiving heat from the semiconductor die 150, the heat flows to the TIM 320, 321 without flowing through any intervening layer or material. Heat from the TIM 320, 321 can then be transferred (520) directly into a heat-dissipative element 110 that is in physical contact with the TIM 320, 321 (e.g., again without flowing through any intervening layer or material). The heat-dissipative element 110 can then transfer (530) heat directly into a coolant liquid 210 (again without flowing through any intervening layer or material. Accordingly, heat can flow from the semiconductor die 150 to the coolant liquid 210 without flowing through a protective lid 130 and without flowing through a second TIM layer.

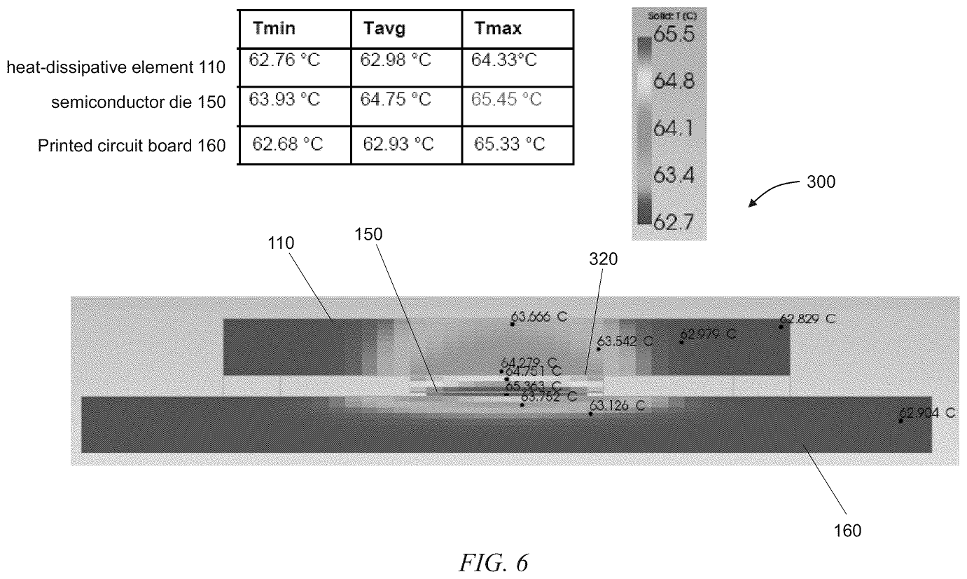

Several simulations were carried out to evaluate thermal operation of example cooling assemblies. FIG. 6 plots steady-state temperatures reached for a cooling assembly 300 like that of FIG. 3B in which the semiconductor die 150 was modeled as a 2-dimensional heat source dissipating 5 Watts of heat continuously and essentially at the interface between the semiconductor die 150 and the PCB 160. The die size was 3.4 mm×3.4 mm and approximately 0.3 mm thick with a thermal conductivity of 148 W m⁻¹ K⁻¹. A layer of ball grid solder connection (65 microns thick) was assumed below the semiconductor die 150 to connect the die to the PCB 160. The thermal conductivity of this layer was modeled as 5 W m⁻¹ K⁻¹. The PCB measured 15 mm×15 mm and was modeled with two thermal conductivites 35 W m⁻¹ K⁻¹ and 0.35 W ml K⁻¹ for in-plane and through-board directions, respectively. A single TIM 320 of indium solder (50 microns thick, thermal conductivity of 70 W m⁻¹ K⁻¹) was located between the semiconductor die 150 and the heat-dissipative element 110. The heat-dissipative element 110 was copper (thermal conductivity of 387 W m⁻¹ K⁻¹) having a thickness of 1 mm above the semiconductor die 150 and a BEC 115 and measuring 10 mm×10 mm. A total boiling surface area of the heat-dissipative element 110 was 2.4 cm2. Coolant liquid 210 (modeled using Novec 7100 fluid, boiling point of 61° C.) could flow under the heat-dissipative element 110 to the semiconductor die 150. The results show a temperature range in the assembly from about 63.5° C. to about 65.5° C. The maximum temperature in the semiconductor die 150 is 65.45° C. Results from the models suggest that adequate thermal dissipation can be obtained without the presence of the protective lid 130 of FIG. 1.

The cooling assemblies and related methods described herein can be implemented in different configurations. Some example configurations are listed below. The listed method configurations may be used in combination with some or all of the listed apparatus configurations.
(1) A cooling assembly including a semiconductor die, the cooling assembly comprising: the semiconductor die having a first surface; a heat-dissipative element having a second surface on a first side of the heat-dissipative element and a third surface on a second side of the heat-dissipative element opposite the second surface, wherein the third surface is arranged to physically contact a coolant liquid; and a thermal interface material in physical contact with the first surface of the semiconductor die and in physical contact with the second surface of the heat-dissipative element.
(2) The cooling assembly of configuration (1), wherein: the first surface, the second surface, and the third surface extend in planar directions that are approximately parallel to each other; and substantially all of the third surface is arranged to physically contact the coolant liquid.
(3) The cooling assembly of configuration (1) or (2), wherein: the semiconductor die occupies a first area that extends in directions approximately parallel to the first surface; the heat-dissipative element occupies a second area that extends in directions approximately parallel to the first surface; and the second area is no more that 20% larger than the first area.
(4) The cooling assembly of any one of configurations (1) through (3), wherein no mechanical fasteners are used to retain the heat-dissipative element against the semiconductor die.
(5) The cooling assembly of any one of configurations (1) through (4), wherein the thermal interface material is a first thermal interface material, the cooling assembly further comprising: a second thermal interface material different from the first thermal interface material and located around the first thermal interface material, in physical contact with the first surface of the semiconductor die, and in physical contact with the second surface of the heat-dissipative element.
(6) The cooling assembly of configuration (5), wherein the first thermal interface material covers more than 50% of the first surface.
(7) The cooling assembly of any one of configurations (1) through (6), further comprising: a printed circuit board supporting the semiconductor die, wherein at least a portion of the heat-dissipative element extends over peripheral edges of the semiconductor die and is adhered to the printed circuit board.
(8) The cooling assembly of any one of any one of configurations (1) through (7), wherein the semiconductor die comprises a microprocessor.
(9) The cooling assembly of configuration (8), wherein the microprocessor is a central processing unit.
(10) The cooling assembly of configuration (8) or (9), wherein the semiconductor die is configured to draw from 300 watts to 600 watts of electrical power when operating.
(11) The cooling assembly of any one of configurations (8) through (10), wherein the heat-dissipative element comprises a conductive metal.
(12) The cooling assembly of any one of configurations (8) through (10), wherein the heat-dissipative element comprises a semiconductor.
(13) The cooling assembly of any one of configurations (8) through (10), wherein the heat-dissipative element comprises a ceramic.
(14) The cooling assembly of any one of configurations (8) through (13), wherein the heat-dissipative element has a thermal conductivity of at least 20 W m⁻¹ K⁻¹.
(15) The cooling assembly of any one of configurations (8) through (14), wherein the third surface includes a boiling enhancement coating.
(16) The cooling assembly of configuration (15), wherein the heat-dissipative element includes at least one smooth surface for which a normal direction from the at least one smooth surface points away from the semiconductor die, the at least one smooth surface configured for one or both of picking up at least the heat-dissipative element with a vacuum chuck and marking to identify the semiconductor die.
(17) The cooling assembly of any one of configurations (8) through (16), wherein the first thermal interface material is a thermally-conductive adhesive.
(18) The cooling assembly of any one of configurations (8) through (16), wherein the first thermal interface material is a thermally-conductive gel.
(19) The cooling assembly of any one of configurations (8) through (16), wherein the first thermal interface material comprises a polymer having a suspension of thermally-conductive particles.
(20) The cooling assembly of any one of configurations (8) through (16), wherein the first thermal interface material comprises a malleable foil.
(21) The cooling assembly of any one of configurations (8) through (16), wherein the first thermal interface material comprises a solder.
(22) The cooling assembly of any one of configurations (8) through (21), further comprising at least one mechanical fastener to retain the heat-dissipative element and thermal interface material against the semiconductor die.
(23) The cooling assembly of any one of configurations (8) through (2), wherein the semiconductor die is a first semiconductor die and the thermal interface material is a first thermal interface material, the cooling assembly further comprising: at least one second semiconductor die having a fourth surface; and a second thermal interface material in physical contact with the fourth surface of the second semiconductor die and in physical contact with the second surface of the heat-dissipative element.
(24) A method of cooling a semiconductor die, the method comprising: receiving heat directly from a first surface of the semiconductor die in a thermal interface material that is in physical contact with the first surface of the semiconductor die; transferring heat from the thermal interface material directly into a second surface of a heat-dissipative element that is in physical contact with the thermal interface material; and transferring heat from a third surface of the heat-dissipative element directly into a coolant liquid that is in physical contact with the third surface.
(25) The method of (24), wherein: the first surface, the second surface, and the third surface extend in planar directions that are approximately parallel to each other; and substantially all of the third surface is arranged to physically contact the coolant liquid.
(26) The method of (24) or (25), wherein: the semiconductor die occupies a first area that extends in directions approximately parallel to the first surface; the heat-dissipative element occupies a second area that extends in directions approximately parallel to the first surface; and the second area is no more that 20% larger than the first area.
(27) The method of any one of (24) through (26), further comprising: using no mechanical fasteners to retain the heat-dissipative element against the semiconductor die.
(28) The method of any one of (24) through (27), wherein the thermal interface material is a first thermal interface material, the method further comprising: receiving heat directly and in parallel from the first surface of the semiconductor die in a second thermal interface material that is located around the first thermal interface material and is in physical contact with the first surface of the semiconductor die; transferring heat from the second thermal interface material directly into the second surface of a heat-dissipative element.
(29) The method of any one of (24) through (28), further comprising relieving mechanical stress, with the thermal interface material, between the semiconductor die and the heat-dissipative element arising from a difference in a first coefficient of thermal expansion for the semiconductor die and a second coefficient of thermal expansion for the heat-dissipative element.
(30) The method of any one of (24) through (29), wherein the semiconductor die comprises a microprocessor.
(31) The method of (30), wherein the microprocessor is a central processing unit.
(32) The method of (30) or (31), further comprising drawing from 300 watts to 600 watts of electrical power to operate the semiconductor die.
(33) The method of any one of (30) through (32), wherein the heat-dissipative element comprises a conductive metal.
(34) The method of any one of (30) through (32), wherein the heat-dissipative element comprises a semiconductor.
(35) The method of any one of (30) through (32), wherein the heat-dissipative element comprises a ceramic.
(36) The method of any one of (30) through (35), wherein the heat-dissipative element has a thermal conductivity of at least 20 W m⁻¹ K⁻¹
(37) The method of any one of (30) through (36), wherein a surface of the heat-dissipative element includes a boiling enhancement coating.
(38) The method of any one of (30) through (37), wherein the first thermal interface material is a thermally-conductive adhesive.
(39) The method of any one of (30) through (37), wherein the first thermal interface material is a thermally-conductive gel.
(40) The method of any one of (30) through (37), wherein the first thermal interface material comprises a polymer.
(41) The method of any one of (30) through (37), wherein the first thermal interface material comprises a malleable foil.
(42) The method of any one of (30) through (37), wherein the first thermal interface material comprises a solder.
(43) The method of any one of (30) through (42), wherein at least one mechanical fastener retains the heat-dissipative element and thermal interface material against the semiconductor die.
(44) A method of making a cooling assembly to cool a semiconductor die, the method comprising: applying a thermal interface material to a first surface of the semiconductor die; and physically contacting a second surface of a heat-dissipative element to the thermal interface material, wherein the heat-dissipative element includes a boiling enhancement coating on a third surface to physically contact a coolant liquid.
(45) The method of (44), wherein the thermal interface material is a thermally-conductive adhesive that adheres the heat-dissipative element to the semiconductor die.
(46) The method of (44) or (45), wherein no mechanical fasteners are used to retain the heat-dissipative element against the thermal interface material.
(47) The method of any one of (44) through (46), wherein the thermal interface material comprises a polymer having a suspension of thermally-conductive particles.
(48) The method of any one of (44) through (46), wherein the thermal interface material comprises indium solder.
(49) The method of any one of (44) through (46), wherein the thermal interface material is a first thermal interface material, the method further comprising: applying a second thermal interface material to a first surface of the semiconductor die, the second thermal interface material located peripherally around the first thermal interface material on the first surface of the semiconductor die; and physically contacting the second surface of the heat-dissipative element to the second thermal interface material.
(50) The method of any one of (44) through (49), wherein: the semiconductor die occupies a first area that extends in directions approximately parallel to the first surface; the heat-dissipative element occupies a second area that extends in the directions approximately parallel to the first surface; and the second area is no more that 20% larger than the first area.
(51) The method of any one of (44) through (50), wherein the semiconductor die comprises a microprocessor.
(52) The method of any one of (44) through (51), further comprising: adhering a portion of the heat-dissipative element to a printed circuit board on which the semiconductor die is mounted.
(53) The method of any one of (44) through (52), wherein the heat-dissipative element includes a boiling enhancement coating and at least one smooth surface having a normal direction pointing away from the semiconductor die, the method further comprising: picking up at least the heat-dissipative element by the at least one smooth surface with a vacuum chuck.
(54) The method of (53), further comprising marking the smooth surface to identify the semiconductor die.
(55) A cooling assembly including a semiconductor die, the cooling assembly comprising: the semiconductor die having a first surface; a heat-dissipative element having a second surface on a first side of the heat-dissipative element and a third surface on a second side of the heat-dissipative element opposite the second surface, wherein the third surface is arranged to thermally couple to a coolant liquid; and a thermal interface material disposed between the first surface of the semiconductor die and the second surface of the heat-dissipative element to transfer heat from the semiconductor die to the heat-dissipative element, wherein there is no protective lid disposed between the semiconductor die and the heat-dissipative element.
(56) The cooling assembly of configuration (55), wherein the thermal interface material is a first thermal interface material and there is no second thermal interface material disposed between the semiconductor die and the coolant liquid.
(57) The cooling assembly of configuration (55) or (56), wherein the first thermal interface material comprises multiple layers of materials.
(58) The cooling assembly of configuration (55) or (56), wherein the first thermal interface material comprises indium solder.
(59) The cooling assembly of configuration (55) or (56), wherein the first thermal interface material comprises a thermally-conductive adhesive.
(60) The cooling assembly of any one of configurations (55) through (59), wherein: the semiconductor die occupies a first area that extends in directions approximately parallel to the first surface; the heat-dissipative element occupies a second area that extends in directions approximately parallel to the first surface; and the second area is no more that 20% larger than the first area.
(61) The cooling assembly of any one of configurations (55) through (60), wherein no mechanical fasteners are used to retain the heat-dissipative element against the semiconductor die.
(62) The cooling assembly of any one of configurations (55) through (61), wherein the thermal interface material is a first thermal interface material, the cooling assembly further comprising: a second thermal interface material different from the first thermal interface material and located around the first thermal interface material, in physical contact with the first surface of the semiconductor die, and in physical contact with the second surface of the heat-dissipative element.
(63) The cooling assembly of (62), wherein the first thermal interface material covers more than 50% of the first surface.
(64) The cooling assembly of any one of configurations (55) through (63), further comprising: a printed circuit board supporting the semiconductor die, wherein at least a portion of the heat-dissipative element extends over peripheral edges of the semiconductor die and is adhered to the printed circuit board.
(65) The cooling assembly of any one of configurations (55) through (64), further comprising: a boiling enhancement coating on the third surface of the heat-dissipative element, wherein the heat-dissipative element includes at least one smooth surface for which a normal direction from the at least one smooth surface points away from the semiconductor die, the at least one smooth surface configured for one or both of picking up at least the heat-dissipative element with a vacuum chuck and marking to identify the semiconductor die.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that inventive embodiments may be practiced otherwise than as specifically described. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

Unless stated otherwise, the terms “approximately” and “about” are used to mean within +20% of a target (e.g., dimension or orientation) in some embodiments, within +10% of a target in some embodiments, within +5% of a target in some embodiments, and yet within +2% of a target in some embodiments. The terms “approximately” and “about” can include the target. The term “essentially” is used to mean within +3% of a target.

The indefinite articles “a” and “an,” as used herein, unless clearly indicated to the contrary, should be understood to mean “at least one.”

The phrase “and/or,” as used herein, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of” or “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” shall have its ordinary meaning as used in the field of patent law.

As used herein, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A method of cooling a semiconductor die, the method comprising:
receiving heat directly from a first surface of the semiconductor die in a thermal interface material that is in physical contact with the first surface of the semiconductor die;
transferring heat from the thermal interface material directly into a second surface of a heat-dissipative element that is in physical contact with the thermal interface material;
transferring heat from a boiling enhancement coating disposed on a third surface of the heat-dissipative element directly into a coolant liquid that is in physical contact with the boiling enhancement coating and the third surface.

2. The method of claim 1, wherein:
the first surface, the second surface, and the third surface extend in planar directions that are approximately parallel to each other; and
substantially all of the third surface is arranged to physically contact the coolant liquid.

3. The method of claim 1, wherein:
the semiconductor die occupies a first area that extends in directions approximately parallel to the first surface;
the heat-dissipative element occupies a second area that extends in directions approximately parallel to the first surface; and
the second area is no more that 20% larger than the first area.

4. The method of claim 1, further comprising:
using no mechanical fasteners to retain the heat-dissipative element against the semiconductor die.

5. The method of claim 1, wherein the thermal interface material is a first thermal interface material, the method further comprising:
receiving heat directly and in parallel from the first surface of the semiconductor die in a second thermal interface material that is located around the first thermal interface material and is in physical contact with the first surface of the semiconductor die;
transferring heat from the second thermal interface material directly into the second surface of a heat-dissipative element.

6. The method of claim 1, further comprising relieving mechanical stress, with the thermal interface material, between the semiconductor die and the heat-dissipative element arising from a difference in a first coefficient of thermal expansion for the semiconductor die and a second coefficient of thermal expansion for the heat-dissipative element.

7. The method of claim 1, wherein the semiconductor die comprises a microprocessor.

8. The method of claim 7, wherein the microprocessor is a central processing unit.

9. The method of claim 7, further comprising drawing from 300 watts to 600 watts of electrical power to operate the semiconductor die.

10. The method of claim 7, wherein the heat-dissipative element comprises a conductive metal.

11. The method of claim 7, wherein the heat-dissipative element comprises a semiconductor.

12. The method of claim 7, wherein the heat-dissipative element comprises a ceramic.

13. The method of claim 7, wherein the heat-dissipative element has a thermal conductivity of at least 20 W m⁻¹ K⁻¹.

14. The method of claim 7, wherein a surface of the heat-dissipative element includes a boiling enhancement coating.

15. The method of claim 5, wherein the first thermal interface material is at least one of a thermally-conductive adhesive or a thermally-conductive gel.

16. The method of claim 5, wherein the first thermal interface material comprises a polymer.

17. (canceled)

18. (canceled)

19. The method of claim 1, wherein at least one mechanical fastener retains the heat-dissipative element and thermal interface material against the semiconductor die.

20. A cooling assembly including a semiconductor die, the cooling assembly comprising:
a printed circuit board;
the semiconductor die having a first surface, wherein the semiconductor die is mounted on the printed circuit board;
a heat-dissipative element having a second surface on a first side of the heat-dissipative element and a third surface on a second side of the heat-dissipative element opposite the second surface;
a boiling enhancement coating disposed on the third surface, wherein the boiling enhancement coating and the third surface are arranged to thermally couple to a coolant liquid; and
a thermal interface material comprising a solderable conductive adhesive disposed between the first surface of the semiconductor die and the second surface of the heat-dissipative element to transfer heat from the semiconductor die to the heat-dissipative element,
wherein there is no protective lid disposed between the semiconductor die and the heat-dissipative element, and
wherein the heat-dissipative element is configured to attach to the printed circuit board to form a sealed chamber surrounding the semiconductor die, the sealed chamber configured to prevent the coolant liquid from contacting the semiconductor die.

21. The cooling assembly of claim 20, wherein the thermal interface material is a first thermal interface material and there is no second thermal interface material disposed between the semiconductor die and the coolant liquid.

22. The cooling assembly of claim 21, wherein the first thermal interface material comprises multiple layers of materials.

23. The cooling assembly of claim 21, wherein the first thermal interface material further comprises indium solder.

24. The cooling assembly of claim 21, wherein the first thermal interface material further comprises a thermally-conductive adhesive.

25. The cooling assembly of claim 20, wherein:
the semiconductor die occupies a first area that extends in directions approximately parallel to the first surface;
the heat-dissipative element occupies a second area that extends in directions approximately parallel to the first surface; and
the second area is no more than 20% larger than the first area.

26. The cooling assembly of claim 20, wherein no mechanical fasteners are used to retain the heat-dissipative element against the semiconductor die.

27. The cooling assembly of claim 20, wherein the thermal interface material is a first thermal interface material, the cooling assembly further comprising:
a second thermal interface material different from the first thermal interface material and located adjacent to the first thermal interface material, in physical contact with the first surface of the semiconductor die, and in physical contact with the second surface of the heat-dissipative element.

28. The cooling assembly of claim 27, wherein the first thermal interface material covers more than 50% of the first surface.

29. The cooling assembly of claim 20,
wherein at least a portion of the heat-dissipative element extends over peripheral edges of the semiconductor die and is adhered to the printed circuit board.

30. The cooling assembly of claim 20, wherein the heat-dissipative element includes at least one smooth surface for which a normal direction from the at least one smooth surface points away from the semiconductor die, the at least one smooth surface configured for one or both of picking up at least the heat-dissipative element with a vacuum chuck and marking an area of the at least one smooth surface to identify the semiconductor die.

31. A plurality of cooling assemblies, each cooling assembly as claimed in claim 20, wherein:
each cooling assembly of the plurality of cooling assemblies is disposed in a device package to form a plurality of device packages,
the device packages are arrayed on the printed circuit board and spaced apart by no more than 2 mm between adjacent device packages.

32. The plurality of cooling assemblies of claim 31, wherein a volume of space occupies by each device package of the plurality of device packages is no larger than 12 mm×12 mm×8 mm.
